(19) United States
(12) Patent Application Publication
(10) Pub. No.: US 2022/0333234 A1
(43) Pub. Date: Oct. 20, 2022

(54) SYSTEMS AND METHODS FOR LOW TEMPERATURE GROWTH OF PRISTINE, DOPED AND NANOPOROUS GRAPHENE FILMS

(71) Applicant: NUtech Ventures, Lincoln, NE (US)

(72) Inventors: Alexander Sinitskii, Lincoln, NE (US); Angel Torres, Lincoln, NE (US); Gang Li, Lincoln, NE (US)

(21) Appl. No.: 17/856,477

(22) Filed: Jul. 1, 2022

Related U.S. Application Data
(63) Continuation of application No. PCT/US2021/012068, filed on Jan. 4, 2021.
(60) Provisional application No. 62/957,058, filed on Jan. 3, 2020.

(51) Int. Cl. C23C 16/26; C23C 16/56; B01J 23/72; B01J 37/02

(52) U.S. Cl. CPC C23C 16/26; C23C 16/56; B01J 23/72; B01J 37/0215

(57) ABSTRACT

Novel synthetic methods to produce layers or films and flakes of pristine graphene, heteroatom-doped graphene, nanoporous graphene or heteroatom-doped nanoporous graphene using specially designed molecular precursors at temperatures as low as 160° C. using a chemical vapor deposition (CVD) system. The methods enable the realization of graphene-based electronics and technologies due to the low-temperature synthesis, large-area coverage, and scalability of the CVD method by taking advantage of the precursors tendency to polymerize and fuse once on the catalytic metal substrates.

### CROSS-REFERENCES TO RELATED APPLICATIONS

The present application is a continuation of International Application No. PCT/US2021/012068, filed on Jan. 4, 2021, which claims priority to U.S. Provisional Patent Application No. 62/957,058, filed Jan. 3, 2020, entitled “SYSTEMS AND METHODS FOR LOW TEMPERATURE GROWTH OF PRISTINE AND DOPED GRAPHENE FILMS,” which are each hereby incorporated by reference in its entirety herein.

### FEDERALLY SPONSORED RESEARCH OR DEVELOPMENT

This invention was made with Government support under contract numbers CHE1455330 awarded by The National Science Foundation. The Government has certain rights in this invention.

### BACKGROUND

Graphene is an atomically thin sheet of sp²-bonded carbon atoms arranged in a hexagonal lattice [1]. It has unique physical properties and great potential for a variety of applications and technologies [1]. Freestanding graphene has a very high charge carrier mobility of over 200,000 cm²V⁻¹s⁻¹ [2, 3], a Young's modulus of about 1 TPa [4, 5], high thermal conductivity [6, 7], 97% transmittance of visible light [8], all while being a flexible and lightweight material. Graphene has inspired research ranging from bolstering the strength of construction materials [9] and graphene-based clothing for heat dissipation [10] to energy storage [11] and flexible technologies [12].

The original graphene samples were produced by the mechanical exfoliation approach, which relies on exfoliation of graphene from graphite crystals using an adhesive tape [13]. However, this method is time-and labor-consuming and yields very small randomly shaped graphene crystals. Graphene can also be grown on SiC substrates [14], which however are very expensive and difficult to transfer graphene from. An important breakthrough in the field happened in 2009,when researchers demonstrated a scalable growth of large-scale graphene sheets on Cu foils by thermal decomposition of methane at 1000° C. [15]. However, the very high temperature of the synthesis, which is necessary for decomposition of methane or similar precursor molecules, is one of the limitations of the process preventing its integration in manufacturing procedures adopted by the semiconductor industry, as most electronic materials cannot survive such harsh annealing.

The implementation of graphene into functional devices has not yet been fully realized due to limitations imposed by its synthetic methods [16]. On one hand, top-down approaches to isolate freestanding graphene, such as the mechanical exfoliation method [13], provide high-quality graphene flakes, which are small, difficult to transfer to arbitrary substrates and cannot be scaled to suit large-scale industrial requirements. On the other hand, bottom-up methods, such as the carbon precipitation from SiC [14] or the chemical vapor deposition (CVD) synthesis [15], not only produce graphene films with wafer-sized coverage but also provide the versatility required to scale up production [17]. These benefits aside, graphene synthesized via the pyrolysis of carbon sources, such as methane, in the presence of a catalytic metal substrate require temperatures of up to 1000° C. [15]. These high temperatures exceed those tolerable in the production of multilevel electronic devices whose components would be adversely affected [16]. Alternatives to the thermal decomposition of carbon feedstock have been developed to employ plasma-enhanced, microwave plasma, or photo-thermal CVD to enable the dissociation of the hydrocarbon precursors at lower temperatures [18]. Synthesis temperatures as low as 300° C. have been reported for graphene grown by some of these specialized techniques, although the plasma species required for the synthesis can damage the CVD reactor and graphene film lowering the final quality of the material. Therefore, a viable low-temperature alternative to the thermal decomposition of carbon precursors for synthesizing large-area, high-quality graphene films is required to effectively utilize graphene's properties in functional semiconductor technologies.

### SUMMARY

Embodiments of the present disclosure provide chemical vapor deposition (CVD) methods to synthesize graphene from molecular precursors via a surface-catalyzed reaction performed at unprecedentedly low temperatures, e.g., as low as 160° C.

According to an embodiment, a method of forming or growing a graphene layer includes providing a catalytic substrate, depositing a graphene precursor on the catalytic substrate by chemical vapor deposition (CVD) of the graphene precursor to form a layer on the catalytic substrate, and raising a temperature of the substrate to at least about 160° C. to form a graphene layer on the catalytic substrate, e.g., by inducing cyclodehydrogenation of the polymer layer to form the graphene layer on the substrate. In certain embodiments, halogenated, polycyclic precursor molecules are employed. These molecules, which are sublimated and, once in the gas phase, travel to the catalytic surface to undergo the reaction which yields uniform films of graphene at much lower temperatures than previously reported methods. This synthetic procedure enables the direct implementation of graphene into current electronic device manufacturing processes which can easily accommodate the temperature requirements, whereas previous methods require temperatures exceeding those tolerable by such devices. The low-temperature synthesis also enables the deposition of graphene onto flexible technologies without damage to the supporting plastic substrate.

According to certain aspects, the graphene precursor comprises a polycyclic compound or a halogenated polycyclic aromatic compound. In certain aspects, the graphene precursor comprises 3′,6′-dibromo-1,1′:2′,″-terphenyl (C₁₈H₁₂Br_{2,} DBTP). In certain aspects, the graphene precursor comprises 3′,6′-dihalo-1,1′:2′,″-terphenyl (C₁₈H₁₂X₂), wherein X is selected from Cl, Br, I or a combination thereof. In certain aspects, the graphene precursor comprises 6,11-dibromo-1,2,3,4-tetraphenyltriphenylene (C₄₂Br₂H₂₆). In certain aspects, the graphene precursor comprises 6,11-dihalo-1,2,3,4-tetraphenyltriphenylene (C₄₂H₂₆X₂), wherein X is selected from Cl, Br, I or a combination thereof. In certain aspects, the graphene precursor comprises 2,3-di([1,1′-biphenyl]-4-yl)-6,11-dihalo-1,4-diphenyltriphenylene (C₅₄H₃₄X₂), wherein X is selected from Cl, Br, I or a combination thereof. In certain aspects, the graphene precursor comprises 2-([1,1′:2′,1″-terphenyl]-3′-yl)-6,11-dihalo-1,4-diphenyltriphenylene (C₄₈H₃₀X₂), wherein X is selected from Cl, Br, I or a combination thereof.

In certain aspects, the catalytic substrate comprises a metal substrate. In certain aspects, the metal substrate comprises one of Ni, Cu, Ag, Au, Al, Pd, Rh, Ir or Pt.

In certain aspects, the catalytic substrate comprises polycrystalline Cu.

In certain aspects, the raising the temperature induces planarization of the graphene layer.

In certain aspects, the catalytic substrate is provided in a vacuum chamber.

In certain aspects, the catalytic substrate includes a catalytic material on a flexible, plastic substrate.

In certain aspects, the graphene layer is a graphene monolayer.

In certain aspects, the graphene precursor includes carbon (C) atoms specifically substituted with group 13 elements, such as boron (B) atoms, and wherein the graphene layer comprises group-13-element-doped graphene such as B-doped graphene.

In certain aspects, the graphene precursor includes carbon (C) atoms specifically substituted with nitrogen (N) atoms and wherein the graphene layer comprises N-doped graphene.

In certain aspects, the graphene precursor includes carbon (C) atoms specifically substituted with group 15 elements, such as nitrogen (N) atoms, and wherein the graphene layer comprises group-15-element-doped graphene, such as N-doped graphene. Other group 15 elements include P, As, Sb, and Bi.

In certain aspects, the graphene precursor includes carbon (C) atoms specifically substituted with sulfur (S) atoms and wherein the graphene layer comprises S-doped graphene.

In certain aspects, the graphene precursor contains N and S atoms and wherein the graphene layer comprises N,S-doped graphene.

In certain aspects, the graphene monomer includes carbon (C) atoms specifically substituted with a group 15 element and a group 16 element, such as nitrogen (N) and sulfur (S) atoms, and wherein the graphene layer comprises group-15-element-doped and group-16-element-doped graphene such as N- and S-doped graphene

In certain aspects, the graphene precursor contains B and N atoms and wherein the graphene layer comprises B,N-doped graphene.

In certain aspects, the graphene precursor comprises 4-(3,6-dihalo-[1,1′-biphenyl]-2-yl)pyridine (C₁₇H₁₁X₂N), wherein X is selected from Cl, Br, I or a combination thereof, and wherein the graphene layer comprises N-doped graphene.

In certain aspects, the graphene precursor comprises 4,4′-(3,6-dihalo-1,2-phenylene)dipyridine (C₁₆H₁₀X₂N₂), wherein X is selected from Cl, Br, I or a combination thereof, and wherein the graphene layer comprises N-doped graphene.

In certain aspects, the graphene precursor comprises 5-(3,6-dihalo-[1,1′-biphenyl]-2-yl)pyrimidine (C₁₆H₁₀X₂N₂), wherein X is selected from Cl, Br, I or a combination thereof, and wherein the graphene layer comprises N-doped graphene.

In certain aspects, the graphene precursor comprises 5-(3,6-dihalo-2-(pyridin-4-yl)phenyl)pyrimidine (C₁₅H₉X₂N₃), wherein X is selected from Cl, Br, I or a combination thereof, and wherein the graphene layer comprises N-doped graphene.

In certain aspects, the graphene precursor comprises 5,5′-(3,6-dihalo-1,2-phenylene)dipyrimidine (C₁₄H₈X₂N₄), wherein X is selected from Cl, Br, I or a combination thereof, and wherein the graphene layer comprises N-doped graphene.

In certain aspects, the graphene precursor comprises 4-(6,11-dihalo-1,3,4-triphenyltriphenylen-2-yl)pyridine (C₄₁H₂₅X₂N), wherein X is selected from Cl, Br, I or a combination thereof, and wherein the graphene layer comprises N-doped graphene.

In certain aspects, the graphene precursor comprises 4,4′-(6,11-dihalo-1,4-diphenyltriphenylene-2,3-diyl)dipyridine (C₄₀H₂₄X₂N₂), wherein X is selected from Cl, Br, I or a combination thereof, and wherein the graphene layer comprises N-doped graphene.

In certain aspects, the graphene precursor comprises 5-(6,11-dihalo-1,3,4-triphenyltriphenylen-2-yl)pyrimidine (C₄₀H₂₄X₂N₂), wherein X is selected from Cl, Br, I or a combination thereof, and wherein the graphene layer comprises N-doped graphene.

In certain aspects, the graphene precursor comprises 5-(6,11-dihalo-1,4-diphenyl-3-(pyridin-4-yl)triphenylen-2-yl)pyrimidine (C₃₉H₂₃X₂N₃), where X can be Cl, Br, I or a combination of thereof) and wherein the graphene layer comprises N-doped graphene.

In certain aspects, the graphene precursor comprises 5,5′-(6,11-dihalo-1,4-diphenyltriphenylene-2,3-diyl)dipyrimidine (C₃₈H₂₂X₂N₄), wherein X is selected from Cl, Br, I or a combination thereof, and wherein the graphene layer comprises N-doped graphene.

In certain aspects, the graphene precursor includes halogenated polycyclic aromatic molecules that upon dehalogenation and lateral fusion produces nanoporous graphene.

In certain aspects, the graphene precursor is 2-([1,1′-biphenyl]-3-yl)-3-([1,1′:3′,1″-terphenyl]-5′-yl)-6,11-dihalo-1,4- diphenyltriphenylene molecule (C₆₀H₃₈X₂), wherein X is selected from Cl, Br, I or a combination thereof and wherein graphene layer comprises nanoporous graphene.

In certain aspects, the graphene precursor is grown from a mixture of precursors designed for continuous and porous graphenes, and wherein a porosity of the resulting nanoporous graphene is controlled by a ratio of precursors in the mixture.

In certain aspects, the graphene precursor is grown from a mixture of precursors designed for continuous and heteroatom-doped graphenes, and wherein a concentration of heteroatoms in the resulting heteroatom-doped graphene is controlled by a ratio of precursors in the mixture.

In certain aspects, the graphene precursor is grown from a mixture of precursors designed for porous and heteroatom-doped graphenes, and wherein a porosity and a concentration of heteroatoms in the resulting heteroatom-doped porous graphene are controlled by a ratio of precursors in the mixture

### BRIEF DESCRIPTION OF THE DRAWINGS

Embodiments of the present invention will be described in even greater detail below based on the exemplary figures. The invention is not limited to the exemplary embodiments. All features described and/or illustrated herein can be used alone or combined in different combinations in embodiments of the invention. The features and advantages of various embodiments will become apparent by reading the following detailed description with reference to the attached drawings which illustrate the following:

FIG. 1 illustrates a scheme of low-temperature graphene growth from 3′,6′-dibromo-1,1′:2′,1″-terphenyl (DBTP, C₁₈H₁₂Br₂) according to an embodiment.

FIG. 2 illustrates a scheme of low-temperature graphene growth from C₁₈H₁₂X₂ molecules, where X can be Cl, Br, I or a combination thereof, according to an embodiment.

FIG. 3 illustrates a scheme of dehalogenation of C₁₈H₁₂X₂ molecules (X is a halogen, such as Cl, Br, I or a combination thereof) according to an embodiment, and a possible pattern of fusion of the dehalogenated molecular fragments to produce continuous defect-free graphene on a substrate; dehalogenated fragments of these molecules can form tightly packed hole-free two-dimensional arrangements; both dehalogenation and dehydrogenation steps are thermally activated and may occur separately or simultaneously, depending on the synthetic conditions.

FIG. 4 illustrates a scheme of low-temperature graphene growth from 6,11-dibromo-1,2,3,4-tetraphenyltriphenylene (C₄₂H₂₆Br₂) according to an embodiment.

FIG. 5. illustrates a scheme of low-temperature graphene growth from C₄₂H₂₆X₂ molecules, where X can be Cl, Br, I or a combination thereof according to an embodiment.

FIG. 6. illustrates a scheme of dehalogenation of C₄₂H₂₆X₂ molecules (X is a halogen, such as Cl, Br, I or a combination thereof) according to an embodiment, and a possible pattern of fusion of the dehalogenated molecular fragments to produce continuous defect-free graphene on a substrate; dehalogenated fragments of these molecules can form tightly packed hole-free two-dimensional arrangements; both dehalogenation and dehydrogenation steps are thermally activated and may occur separately or simultaneously, depending on the synthetic conditions.

FIG. 7. illustrates a scheme of dehalogenation of C₅₄H₃₄X₂ molecules (X is a halogen, such as Cl, Br, I or a combination thereof) according to an embodiment and a possible pattern of fusion of the dehalogenated molecular fragments to produce continuous defect-free graphene on a substrate; dehalogenated fragments of these molecules can form tightly packed hole-free two-dimensional arrangements; both dehalogenation and dehydrogenation steps are thermally activated and may occur separately or simultaneously, depending on the synthetic conditions.

FIG. 8. illustrates a scheme of dehalogenation of C₄₈H₃₀X₂ molecules (X is a halogen, such as Cl, Br, I or a combination thereof) according to an embodiment and a possible pattern of fusion of the dehalogenated molecular fragments to produce continuous defect-free graphene on a substrate; dehalogenated fragments of these molecules can form tightly packed hole-free two-dimensional arrangements; both dehalogenation and dehydrogenation steps are thermally activated and may occur separately or simultaneously, depending on the synthetic conditions.

FIG. 9. illustrates a scheme of dehalogenation of C₆₀H₃₈X₂ molecules (X is a halogen, such as Cl, Br, I or a combination of thereof) and a possible pattern of fusion of the dehalogenated molecular fragments to produce nanoporous graphene on a substrate; dehalogenated fragments of these molecules cannot form tightly packed hole-free two-dimensional arrangements, which means that regardless of the packing of these fragments on a surface the formation of graphene nanopores is inevitable; both dehalogenation and dehydrogenation steps are thermally activated and may occur separately or simultaneously, depending on the synthetic conditions according to an embodiment.

FIG. 10. illustrates a scheme of low-temperature growth of nitrogen-doped graphene from 5-(6,11-dibromo-1,3,4-triphenyltriphenylen-2-yl)pyrimidine (C₄₀H₂₄Br₂N₂) according to an embodiment.

FIG. 11. illustrates a scheme of low-temperature growth of nitrogen-doped graphene from C₄₀H₂₄X₂N₂ molecules, where X can be Cl, Br, I or a combination thereof according to an embodiment.

FIG. 12. illustrates examples of precursor molecules for nitrogen-doped graphene—in all molecules X can be Cl, Br, I or a combination thereof—according to an embodiment.

FIG. 13. illustrates a scheme of low-temperature growth of nitrogen-doped graphene with tunable nitrogen content by co-deposition of 6,11-dibromo-1,2,3,4-tetraphenyltriphenylene (C₄₂H₂₆Br₂) and 5,5′-(6,11-dibromo-1,4-diphenyltriphenylene-2,3-diyl)dipyrimidine (C₃₈H₂₂Br₂N₄) according to an embodiment; the nitrogen content in the resulting graphene can be tuned by changing the ratio of C₄₂H₂₆Br₂ and C₃₈H₂₂Br₂N₄ molecules in the precursor mixture.

FIG. 14. illustrates characterization of graphene grown on a Cu foil from 3′,6′-dibromo-1,1′:2′,1″-terphenyl (DBTP) molecule shown in FIG. 1. according to an embodiment; panel (a) shows an optical image of a graphene film transferred to a Si/SiO₂ substrate showing continuous, large-area coverage; panel (b) shows Raman spectrum of a graphene film. (c) Optical transmittance spectrum of a graphene film; panel (d) shows an optical photograph of a graphene film transferred onto a glass slide to demonstrate the optical uniformity; the contour of the graphene film is shown by the dotted line; panel (e) shows a survey XPS spectrum of a graphene film on a Si/SiO₂ substrate; panel (f) shows a XPS Cls spectrum of a graphene film on a Si/SiO₂ substrate; panel (g) shows a TEM image of a graphene film; panel (h) shows an electron diffraction pattern of a graphene film.

FIG. 15. illustrates electrical characterization of graphene grown on a Cu foil from 3′,6′-dibromo-1,1′:2′,1″-terphenyl (DBTP) molecule shown in FIG. 1. according to an embodiment; panel (a) shows a scheme of a graphene-based field-effect transistor (FET) device; panel (b) shows an AFM image of a graphene FET; panel (c) shows the drain-source current (I_{DS})-drain-source voltage (V_{DS}) dependencies measured at different gate voltages (V_{G}) ranging from −40 to 40 V for a representative graphene FET; panel (d) shows the drain-source current (I_{DS})-gate voltage (V_{G}) dependencies for a representative graphene FET.

### DETAILED DESCRIPTION

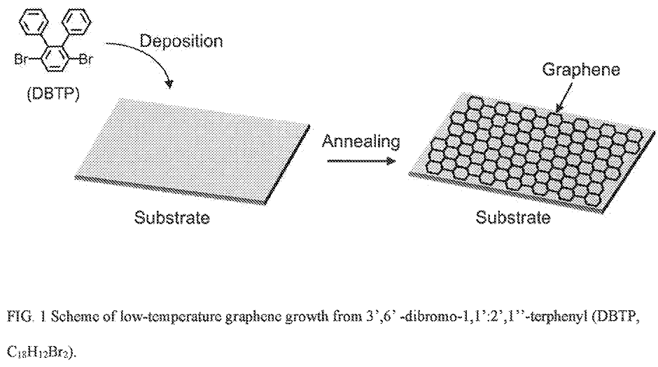

Embodiments of the present disclosure provide chemical vapor deposition (CVD) methods to synthesize graphene from molecular precursors via a surface-catalyzed reaction performed at unprecedentedly low temperatures, e.g., as low as 160° C. FIG. 1 shows an example of one possible graphene precursor that can be deposited on a substrate, such as a copper foil, and upon annealing at a temperature as low as 160° C. convert into graphene. For comparison, baking of poly(methyl methacrylate) (PMMA), a common electron beam lithography resist used for patterning of electronic devices, is typically done at 160° C.—this demonstrates that this new CVD procedure is compatible with practically all chemicals and materials used in semiconductor industry. Herein, embodiments provide CVD synthesis of monolayer graphene with measured mobilities of over 2000 cm² V⁻¹ s⁻¹, which is comparable to or exceeds values reported for CVD-grown graphene samples prepared in other studies from different precursors at considerably higher temperatures.

An immediate enhancement to integrated circuit (IC) performance can be noted in back end of line (BEOL) interconnection technologies. BEOL is a stage of the IC fabrication process which connects individual devices (capacitors, resistors, transistors, etc.) via a conductive path commonly made of copper or aluminum. Synthesizing graphene on those copper or aluminum interconnects, using the low-temperature synthesis methods herein, will produce graphene-copper or graphene-aluminum interconnects with improved capabilities. This can address the obstacles, such as the increased resistivity of copper interconnects, that these technologies face caused by the progressive miniaturization of ICs.

In one particular embodiment, the graphene monomer includes 3′,6′-dibromo-1,1′:2′,1″-terphenyl (DBTP, C₁₈H₁₂Br₂), which is illustrated by FIG. 1. The process is accompanied by debromination of the molecular precursors as well as by intra and inter-molecular fusion of the benzene rings, which results in the formation of continuous graphene sheets.

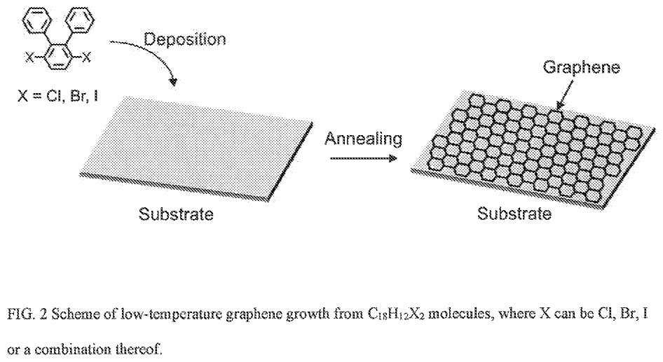

In certain embodiments, molecules that are structurally related DBTP can be used as graphene precursors for the described graphene growth. For example, these molecules can contain other halogen atoms instead of or in addition to bromine atoms, as shown in FIG. 2 for the family of C₁₈H₁₂X₂ molecules, where X can be Cl, Br, I or a combination of thereof. These C₁₈H₁₂X₂ molecules can be deposited on a substrate, such as a copper foil, and produce graphene upon annealing at a temperature as low as 160° C. The process is accompanied by dehalogenation of the molecular precursors as well as by intra and inter-molecular fusion of the benzene rings, which results in the formation of continuous graphene sheets.

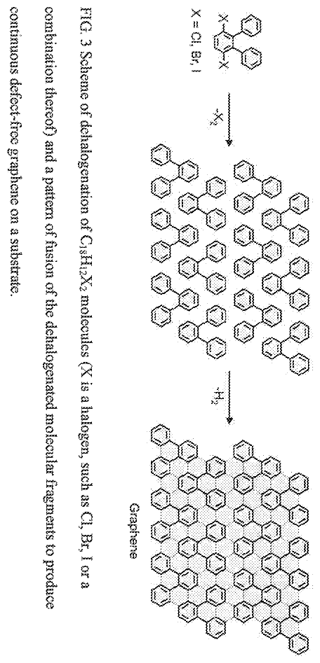

The important feature of the molecules shown in FIG. 1 and FIG. 2 is that their dehalogenated fragments can be spatially arranged on a surface to form a continuous, defect-free graphene sheet upon their thermally activated fusion, see FIG. 3. FIG. 3 shows one of many possible arraignments of the dehalogenated fragments that can produce a continuous, defect-free graphene sheet upon their thermally activated fusion. The fusion process is accompanied by the dehydrogenation of the benzene rings. The dehalogenation and dehydrogenation steps may occur separately or simultaneously, depending on the synthetic conditions.

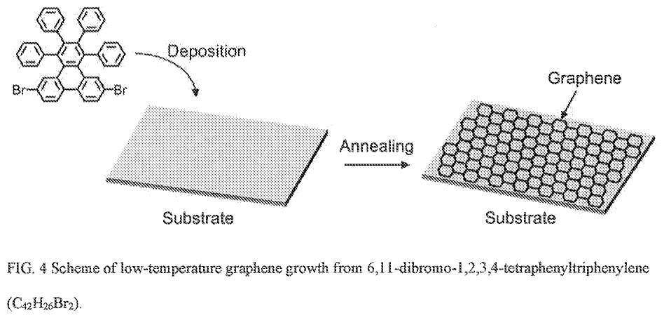

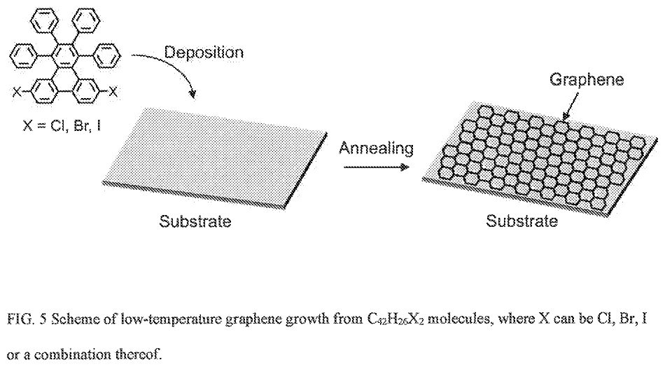

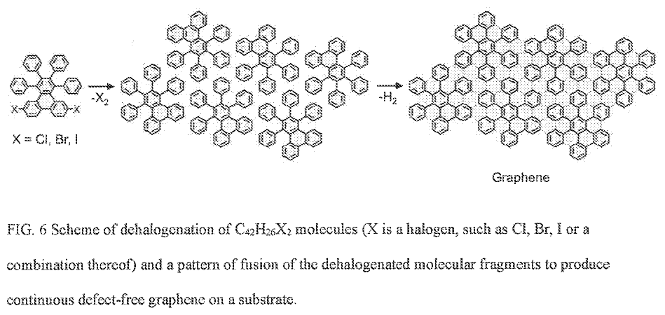

In certain embodiments, the graphene precursor includes 6,11-dibromo-1,2,3,4-tetraphenyltriphenylene (C₄₂H₂₆Br₂). This is illustrated by FIG. 4, which shows the deposition of this graphene precursor on a substrate, such as a copper foil, followed up by the annealing at a temperature as low as 160° C. In certain embodiments, structurally related C₄₂H₂₆X₂ molecules, where X can be Cl, Br, I or a combination of thereof, can be used as graphene precursors, as shown in FIG. 5. As in the case of DBTP (FIG. 1) and related molecules (FIG. 2), which form dehalogenated fragments that can be spatially arranged on a surface to form a continuous, defect-free graphene sheet upon their thermally activated fusion (FIG. 3), similar two-dimensional arrangements can be constructed for the dehalogenated fragments of the molecules shown in FIG. 4 and FIG. 5, which can be seen in FIG. 6.

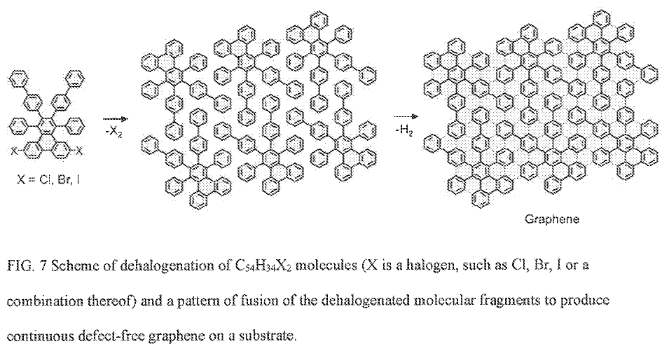

In general, halogenated polycyclic aromatic molecules for which the dehalogenated fragments can form tightly packed hole-free two-dimensional arrangements as shown for molecules in FIG. 3 and FIG. 6 are expected to work as graphene precursors in the described synthesis. In another embodiment, which satisfied this condition, C₅₄H₃₄X₂ molecules shown in FIG. 7, where X can be Cl, Br, I or a combination of thereof, can be used as graphene precursors. Dehalogenated fragments of these molecules form tightly packed hole-free two-dimensional arrangements, which is shown in FIG. 7, and then form a continuous, defect-free graphene sheet upon annealing. These C₅₄H₃₄X₂ molecules can be deposited on a substrate, such as a copper foil, and produce graphene upon annealing at a temperature as low as 160° C.

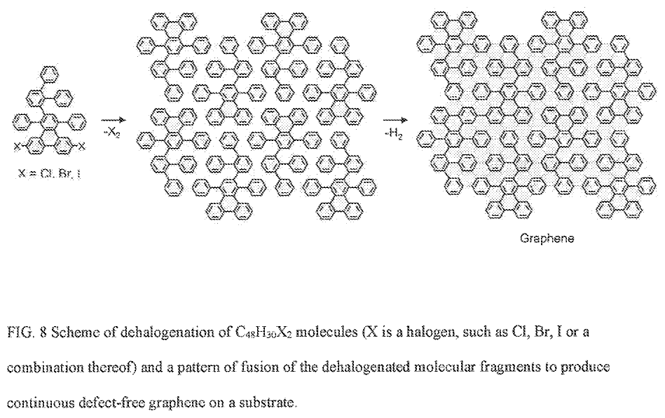

In certain embodiments, C₄₈H₃₀X₂ molecules shown in FIG. 8, where X can be Cl, Br, I or a combination of thereof, can be used as graphene precursors. These C₄₈H₃₀X₂ molecules can be deposited on a substrate, such as a copper foil, and produce graphene upon annealing at a temperature as low as 160° C. Dehalogenated fragments of these molecules form tightly packed hole-free two-dimensional arrangements, which is shown for molecules in FIG. 8, and then form a continuous, defect-free graphene sheet upon annealing. As in previous examples, FIG. 8 shows one of many possible arraignments of the dehalogenated fragments that can produce a continuous, defect-free graphene sheet upon their thermally activated fusion. The fusion process is accompanied by the dehydrogenation of the benzene rings. The dehalogenation and dehydrogenation step may occur separately or simultaneously, depending on the synthetic conditions.

For some halogenated polycyclic aromatic molecules their dehalogenated fragments cannot form tightly packed hole-free two-dimensional arrangements as exemplified by FIG. 3, FIG. 6, FIG. 7 and FIG. 8. Tightly packed two-dimensional arrangements of dehalogenated fragments of such molecules contain nanoscopic holes. If used for the described low-temperature synthetic procedure, such molecules will produce nanoporous graphene. In nanoporous graphene, some of the carbon atoms in the two-dimensional graphene lattice are missing, thus forming tiny pores. Nanoporous graphene has been proposed for a variety applications including electronics [19, 20], selective nanosieves for sequencing [21, 22], ion transport [23, 24], gas separation [25, 26], as well as water desalination and purification [27, 28]. A remarkable selectivity in molecular sieving could be achieved if the pore size and shape match those of relevant target species, such as amino acids, gas molecules or single ions.

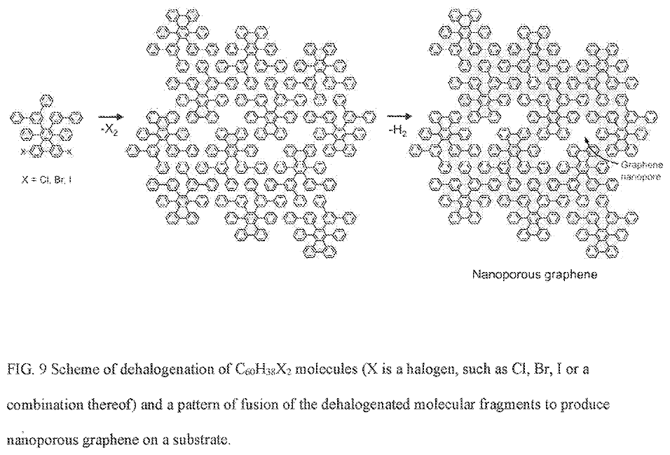

In some embodiments, C₆₀H₃₈X₂ molecules shown in FIG. 9, where X can be Cl, Br, I or a combination of thereof, can be used as precursors for nanoporous graphene. These C₆₀H₃₈X₂ molecules can be deposited on a substrate, such as a copper foil, and produce nanoporous graphene upon annealing at a temperature as low as 160° C. Because of the shape of these molecules, tightly packed two-dimensional arrangements of their dehalogenated fragments will contain nanoscopic holes, as shown in FIG. 9. As in previous examples, FIG. 9 shows one of many possible arraignments of the dehalogenated fragments, but for all such arrangement certain nanoscopic holes will be present. The thermally activated fusion of these fragments on a substrate at temperature as low as 160° C., which is accompanied by the dehydrogenation of the benzene rings, results in the formation of nanoscopic graphene. The dehalogenation and dehydrogenation step may occur separately or simultaneously, depending on the synthetic conditions.

Another important advantage of the described procedures is that they may be modified to produce graphene samples doped with heteroatoms, such as N, S, B, O and P, which are interesting for a variety of applications. For example, nitrogen-doped graphene is generally considered as a promising material for electronics [29], electrochemistry [30, 31], sensing [32], energy storage [33] and catalysis [34, 35]. In addition to the growth at unprecedentedly low temperatures, the use of specially designed molecular precursors allows precise control over the doping levels and the uniformity of the special distribution of dopants in graphene layers or films, which have not been demonstrated in samples prepared by other approaches.

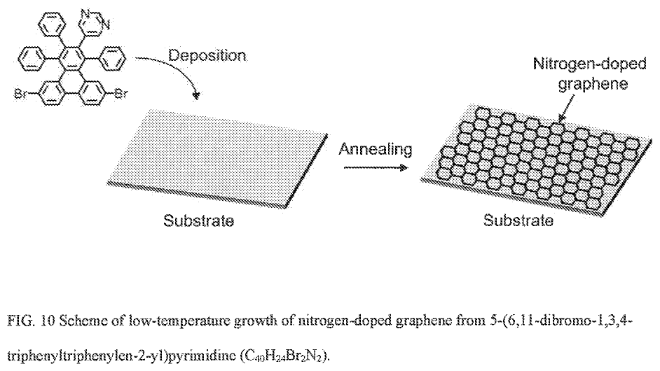

In certain embodiments, 5-(6,11-dibromo-1,3,4-triphenyltriphenylen-2-yl)pyrimidine (C₄₀H₂₄Br₂N₂, see FIG. 10) can be used as a precursor for the growth of nitrogen-doped graphene. These molecules can be deposited on a substrate, such as a copper foil, and produce graphene upon annealing at a temperature as low as 160° C. (FIG. 10). The process is accompanied by debromination of the molecular precursors as well as by intra and inter-molecular fusion of the benzene rings, which results in the formation of continuous sheets of nitrogen-doped graphene.

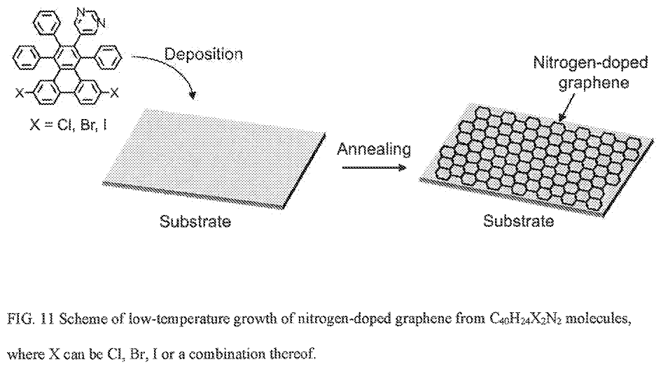

In certain embodiments, C₄₀H₂₄X₂N₂ molecules structurally similar to 5-(6,11-dibromo-1,3,4-triphenyltriphenylen-2-yl)pyrimidine (C₄₀H₂₄Br₂N_{2,} see FIG. 10), in which X can be Cl, Br, I or a combination of thereof, can be used as precursors for the growth of nitrogen-doped graphene (FIG. 11). These molecules can be deposited on a substrate, such as a copper foil, and produce nitrogen-doped graphene upon annealing at a temperature as low as 160° C. (FIG. 11). The process is accompanied by dehalogenation of the molecular precursors as well as by intra and inter-molecular fusion of the benzene rings, which results in the formation of continuous sheets of nitrogen-doped graphene.

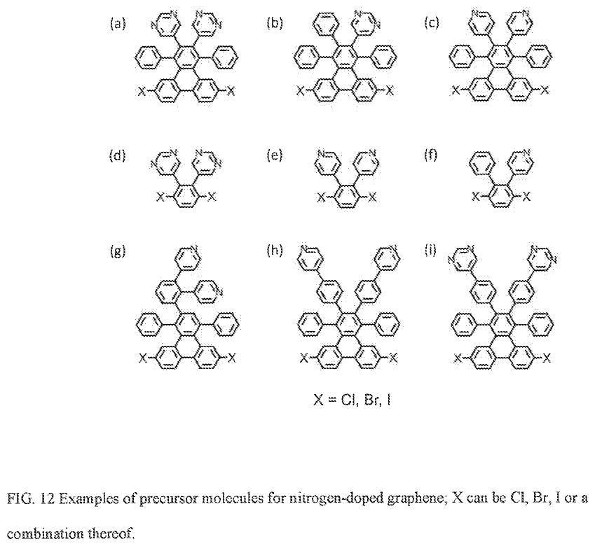

In certain embodiments, halogenated polycyclic aromatic molecules containing at least one nitrogen atom can serve as precursors for nitrogen-doped graphene. These molecules include but are not limited to those shown in FIG. 12. In all molecules shown in FIG. 12, X can be Cl, Br, I or a combination of thereof. These molecules can be deposited on a substrate, such as a copper foil, and produce nitrogen-doped graphene upon annealing at a temperature as low as 160° C.

In certain embodiments, halogenated polycyclic aromatic molecules containing at least one boron atom can serve as precursors for boron-doped graphene. In certain embodiments, halogenated polycyclic aromatic molecules containing at least one sulfur atom can serve as precursors for sulfur-doped graphene. In certain embodiments, halogenated polycyclic aromatic molecules containing at least one oxygen atom can serve as precursors for oxygen-doped graphene. In certain embodiments, halogenated polycyclic aromatic molecules containing at least one phosphorus atom can serve as precursors for phosphorus-doped graphene.

In certain embodiments, halogenated polycyclic aromatic molecules containing any combination of different heteroatoms can serve as precursors for heteroatom-doped graphene. For example, a halogenated polycyclic aromatic molecule containing both N and B atoms can serve as a precursor for BN-doped graphene. These molecules can be deposited on a substrate, such as a copper foil, and produce heteroatom-doped graphene upon annealing at a temperature as low as 160° C.

Heteroatoms can also be introduced into nanoporous graphene. In certain embodiments, halogenated polycyclic aromatic molecules (1) contain any combination of different heteroatoms and (2) have such shapes that all possible tightly packed two-dimensional arrangements of the dehalogenated fragments of these molecules will contain nanoscopic holes can serve as precursors for heteroatom-doped graphene. These molecules can be deposited on a substrate, such as a copper foil, and produce heteroatom-doped nanoporous graphene upon annealing at a temperature as low as 160° C.

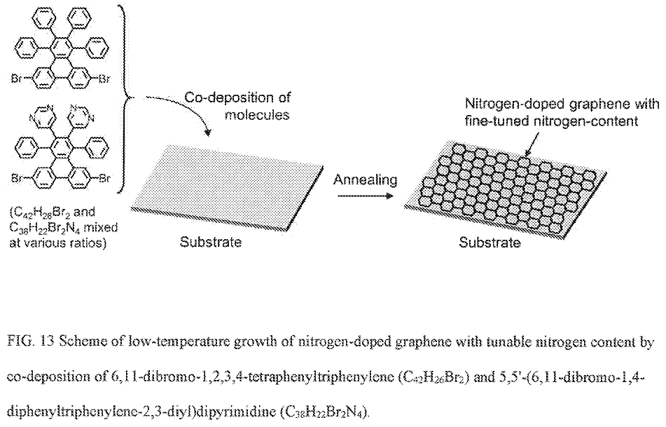

In some embodiments, a mixture of two or more halogenated polycyclic aromatic molecules can be used to grow graphene by the described approach. For example, 6,11-dibromo-1,2,3,4-tetraphenyltriphenylene (C₄₂H₂₆Br₂) and 5,5′-(6,11-dibromo-1,4-diphenyltriphenylene-2,3-diyl)dipyrimidine (C₃₈H₂₂Br₂N₄) can be mixed at various ratios and co-deposited on a substrate, such as a copper foil, to produce nitrogen-doped graphene upon annealing at a temperature as low as 160° C. (FIG. 13). In C₃₈H₂₂Bᵣ₂N₄ the N:C ratio is 4:38, which translates to the nitrogen content of about 9.5 at. % in a nitrogen-doped graphene grown from this molecule alone. In graphene grown from C₄₂H₂₆Br₂ there is no nitrogen. By mixing C₄₂H₂₆Br₂ and C₃₈H₂₂Br₂N₄ at various ratios it is possible to precisely control the nitrogen content in the resulting nitrogen-doped graphene in the range from 0 to 9.5 at. % (FIG. 13). Other mixtures of two or several halogenated polycyclic aromatic molecules can be used to grow graphene at low temperatures with fine-tuned composition, structure and properties.

In some embodiments, precursors for continuous and nanoporous graphenes can be mixed at predefined ratios to produce graphene with control porosity. One such example includes the co-deposition of 6,11-dibromo-1,2,3,4-tetraphenyltriphenylene (C₄₂H₂₆Br₂), which produces a continuous graphene using the described approach (FIGS. 6), and 2-([1,1′-biphenyl]-3-yl)-3-([1,1′:3′,1″-terphenyl]-5′-yl)-6,11- dibromo-1,4-diphenyltriphenylene (C₆₀H₃₈Br₂), which produces nanoporous graphene using the described approach (FIG. 9). In this example, the increased content of C₆₀H₃₈Br₂ in the mixture translates in the increased concentration of pores in the resulting nanoporous graphene. The mixture of these molecules can be deposited on a substrate, such as a copper foil, and produce graphene upon annealing at a temperature as low as 160° C. The process is accompanied by debromination of the molecular precursors as well as by intra and inter-molecular fusion of the benzene rings, which results in the formation of continuous sheets of nanoporous graphene with a precisely controlled concentration of pores.

In certain embodiments, the catalytic substrate comprises a metal substrate, including a metal material such as Ni, Cu, Ag, Au, Al, Pd, Rh, Ir or Pt. In one particular embodiment, the catalytic substrate comprises polycrystalline Cu. In certain aspects, the catalytic substrate is provided in a vacuum chamber.

In certain aspects, the catalytic substrate includes a catalytic material on a flexible, plastic substrate. Flexible technologies (e.g., photovoltaics, thin-film displays, thin-film transistor technologies, etc.) made from a variety of materials can greatly benefit from the low-temperature synthesis of graphene, heteroatom-doped graphene, nanoporous graphene or heteroatom-doped nanoporous graphene, as disclosed herein. Many of the flexible substrates are made of plastic materials that have much lower temperature tolerances than conventional rigid substrates, so the synthesis method embodiments provide a viable way to implement the remarkable properties of graphene to a quickly emerging class of electronics.

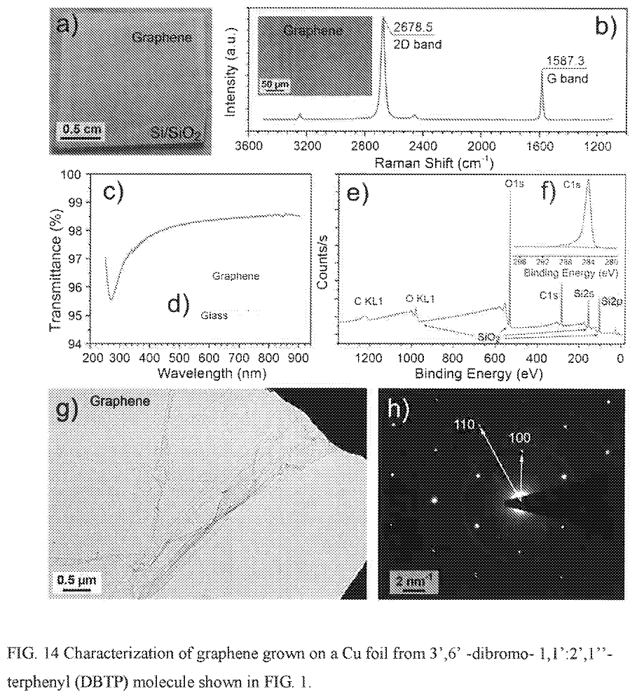

High quality of graphene samples prepared by the described low-temperature growth method was confirmed by a variety of characterization techniques including scanning electron microscopy (SEM), optical microscopy, transmission electron microscopy (TEM), electron diffraction, UV-visible spectroscopy, Raman spectroscopy, X-ray photoelectron spectroscopy (XPS), and electrical property measurements. Representative characterization data for graphene samples grown by depositing the 3′,6′-dibromo-1,1′:2′,1″-terphenyl (DBTP) molecule (FIG. 1) onto an electrochemically polished polycrystalline Cu foil at 160° C. are shown in FIG. 14.

According to an embodiment, graphene may be synthesized on electrochemically polished (electropolished) polycrystalline Cu foils or other catalytic substrates at temperatures as low as 160° C. via the rapid sublimation of the graphene monomer precursor, e.g., DBTP precursor, onto the substrate/Cu catalyst (FIG. 1) in a low-pressure CVD system. At low pressures (for example, ˜500 mTorr using an Ar:H₂ atmosphere at a 5:1 Ar:H₂ flow rate), deposition of DBTP produces a continuous, uniform monolayer of graphene. FIG. 14, panel (a) shows an optical photograph of a uniform graphene monolayer, which is over 1 cm² in size; the graphene sample was originally grown on a Cu substrate and then transferred to a Si/SiO₂ substrate. Large-scale graphene sheets can grow even on polycrystalline Cu foils, as was demonstrated for the deposition of DBTP that can produce graphene that grows over the copper grain boundaries. These graphene sheets have no apparent wrinkles like those reported in high-temperature synthesis methods, due to the opposing thermal expansion coefficient values between graphene and copper [36]. Wrinkles in graphene will result in lower mobilities and suppress electron transport, in general, so that a low-temperature synthesis will minimize these adverse effects resulting in higher quality films [37].

The thickness and structural quality of the DBTP-derived graphene film was evaluated by using Raman spectroscopy, an indispensable and powerful tool to evaluate carbon materials [38, 39]. A typical Raman spectrum for the low-temperature graphene grown from DBTP (FIG. 1) is shown in FIG. 14, panel (b). The Raman spectrum from the film displays the signature features of a high-quality monolayer graphene: a symmetric 2D band at 2680.64 cm⁻¹ with a full width at half maximum (FWHM) of 32 cm⁻¹, a sharp G band at 1587.31 cm⁻¹, and a 2D/G ratio of ˜2. The absence of the D band at about 1350 cm⁻¹ suggests high structural quality of graphene grown by the described low-temperature CVD procedure.

The results of UV-visible spectroscopy of a DBTP-derived graphene film, see FIG. 14, panel (c), are consistent with the previously reported data for monolayer graphene [8]. The graphene sample was originally grown from DBTP on a Cu substrate (FIG. 1) and then transferred to a glass slide. The sample is shown in FIG. 14, panel (d), in which the contour of the barely visible graphene film on a glass substrate is highlighted by the dashed line. The UV-visible spectrum of this sample shows a percent transmittance of about 98% at 550 nm, which is close to the values reported for monolayer graphene in the literature [8].

The surface composition of the sample was characterized by XPS. Photoelectron processes were excited by an AlKα X-ray source with a photon energy of 1486.6 eV (FIG. 14, panel (e)). FIG. 14, panel (f) shows the fitted Cls core level spectrum of the graphene. An asymmetric line profile for the sp² carbon component and a symmetric peak shape for another component were used. The Cls peak consists of two components of binding energies values obtained at ˜284.08 eV and 282.49 eV. The single dominant peak at ˜284.08 eV was assigned to the sp² carbon. The peak at 282.49 eV was formed from carbon-containing contamination. All these results are in good agreement with prior literature reports. No signal was observed for bromine indicating complete debromination of the DBTP precursor to form the graphene film.

TEM characterization of the samples from the DBTP precursor shows continuous graphene sheets (FIG. 14, panel (g)) with bright sixfold diffraction patterns representative of the hexagonal structure of graphene (FIG. 14, panel (h)).

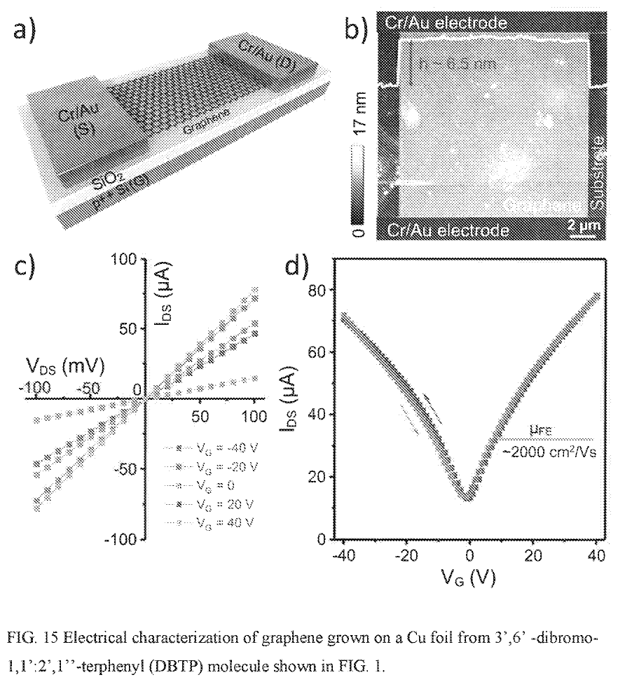

To evaluate the electrical properties of the CVD graphene grown from the DBTP precursor, a two-terminal field-effect transistors (FETs) were fabricated. A scheme of a representative FET device based on a CVD graphene is shown in FIG. 15, panel (a). It demonstrates a graphene device channel bridging Cr/Au source (S) and drain (D) electrodes. The devices were fabricated on a Si/SiO₂ substrate with a 300-nm-thick layer of SiO₂ on a conductive heavily doped p-type Si, which served as the back gate (G) electrode. FIG. 15, panel (b) shows an atomic force microscopy (AFM) image of a representative device. The drain-source current (I_{Ds})-drain-source voltage (V_{DS}) dependencies measured at different gate voltages (V_{G}) ranging from -40 to 40 V were linear (FIG. 15, panel (c)), indicating good Ohmic contacts between graphene and Cr/Au electrodes. The I_{DS}-V_{G} dependencies had a V-shape (FIG. 15, panel (d)), indicating the ambipolar transport that is characteristic for graphene [13]. The fact that these dependencies have a minimum close to 0 V indicates that the CVD graphene grown from the DBTP precursor is not significantly doped by charge impurities. From I_{DS}-V_{G} dependencies we calculated charge carrier mobilities of 2200 cm² V⁻¹ s⁻¹, which further confirms the high quality of the CVD graphene grown from the DBTP precursor.

### EXAMPLE METHODS

Graphene Growth: Graphene was synthesized via a copper-catalyzed homolytic debromination and cyclodehydrogenation of the 3′,6′-dibromo-1,1′:2′,1″-terphenyl (DBTP) monomer via the sublimation of solid GNR precursor, into the hot-walled, low-pressure CVD system. Copper substrates (˜15 mm²,) prepared from a roll of polycrystalline copper foil, were electrochemically polished in an 85% orthophosphoric acid solution using Au/Pt electrodes or soaked in glacial acetic acid for 5 min. Both methods were followed by a rinse with deionized water followed by isopropyl alcohol and blown dry using a stream of N₂ gas. The prepared foils were positioned into the 1-inch inner diameter quartz tube of the two-zone horizontal tube furnace. 1-2 mg of the GNR monomer, held in a quartz combustion boat, was placed on one end of the quartz tube positioned outside of the furnace that will later be heated using a hot plate. The system was pumped down to a system vacuum of ˜5 mTorr using a vacuum pump and filled with 100 sccm of Ar gas for 10 minutes. The H₂ was adjusted to 12.4 sccm, and the furnace was heated to 1000° C. over the course of 20 min and held at 1000° C. for 60 min to thermal anneal the copper foil and allowed to cool to 100° C. where it will be held for the deposition of the GNR monomer. Argon gas (61.9 sccm) was flowed into the CVD system and allowed to equilibrate to the working pressure. The GNR monomer was sublimated, e.g., by setting the hot plate to 150° C. and heating the quartz boat until the material is wholly transferred through the tube: about 5 min. The furnace was heated to 160° C. over the course of about 5 min and held at this temperature for 30 min to induce the cyclodehydrogenation of the deposited DBTP.

Transfer: Two methods were used to transfer the graphene films from the copper substrate. The first was a wet etching of the copper substrate and the second was an electrochemical separation of the graphene film. Graphene on copper substrates was adhered to a glass slide and placed onto the vacuum chuck of the spin coater, covered with a solution of polymethyl methacrylate (PMMA) in anisole (950-A4), spin coated at a rate of 3000 rpm, and allowed to dry.

1.) The coated samples are floated on top of a 0.1 M potassium persulfate solution to until the copper is etched away. The freestanding film is transferred to a large beaker of deionized water, gently rinsed using a glass Pasteur pipette, transferred to another beaker of deionized water, rinsed, transferred to a Si/SiO₂ wafer and allowed to dry. The PMMA film is dissolved using acetone leaving behind the graphene sample.

2.) The coated samples are clamped and submerged in a 0.25 M NaOH solution. Hydrogen bubbling, to separate the coated graphene from the copper, was performed using bulk electrolysis with coulometry. Electrolysis E(V)=−2.4 V

### REFERENCES CITED HEREIN

1. Geim, A. K.; Novoselov, K. S., The rise of graphene. Nat. Mater. 2007, 6, 183-191.
2. Bolotin, K. I.; Sikes, K. J.; Jiang, Z.; Klima, M.; Fudenberg, G.; Hone, J.; Kim, P.; Stormer, H. L., Ultrahigh electron mobility in suspended graphene. Solid State Commun. 2008, 146,351-355.
3. Du, X.; Skachko, I.; Barker, A.; Andrei, E. Y., Approaching ballistic transport in suspended graphene. Nat. Nanotechnol. 2008, 3, 491-495.
4. Bunch, J. S.; van der Zande, A. M.; Verbridge, S. S.; Frank, I. W.; Tanenbaum, D. M.; Parpia, J. M.; Craighead, H. G.; McEuen, P. L., Electromechanical Resonators from Graphene Sheets. Science 2007, 315, 490-493.
5. Lee, C.; Wei, X.; Kysar, J. W.; Hone, J., Measurement of the Elastic Properties and Intrinsic Strength of Monolayer Graphene. Science 2008, 321, 385-388.
6. Balandin, A. A.; Ghosh, S.; Bao, W.; Calizo, I.; Teweldebrhan, D.; Miao, F.; Lau, C. N., Superior Thermal Conductivity of Single-Layer Graphene. Nano Lett. 2008, 8, 902-907.
7. Balandin, A. A., Thermal properties of graphene and nanostructured carbon materials. Nat Mater 2011, 10, 569-581.
8. Nair, R. R.; Blake, P.; Grigorenko, A. N.; Novoselov, K. S.; Booth, T. J.; Stauber, T.; Peres, N. M. R.; Geim, A. K., Fine Structure Constant Defines Visual Transparency of Graphene. Science 2008, 320, 1308.
9. Papageorgiou, D. G.; Kinloch, I. A.; Young, R. J., Mechanical properties of graphene and graphene-based nanocomposites. Progress in Materials Science 2017, 90, 75-127.
10. Meng, Y.; Zhao, Y.; Hu, C.; Cheng, H.; Hu, Y.; Zhang, Z.; Shi, G.; Qu, L., All-Graphene Core-Sheath Microfibers for All-Solid-State, Stretchable Fibriform Supercapacitors and Wearable Electronic Textiles. Adv. Mater. 2013, 25, 2326-2331.
11. Stoller, M. D.; Park, S.; Zhu, Y.; An, J.; Ruoff, R. S., Graphene-Based Ultracapacitors. Nano Lett. 2008, 8, 3498-3502.
12. Ghany, N. A. A.; Elsherif, S. A.; Handal, H. T., Revolution of Graphene for different applications: State-of-the-art. Surfaces and Interfaces 2017, 9, 93-106.
13. Novoselov, K. S.; Geim, A. K.; Morozov, S. V.; Jiang, D.; Zhang, Y.; Dubonos, S. V.; Grigorieva, I. V.; Firsov, A. A., Electric field effect in atomically thin carbon films. Science 2004, 306, 666-669.
14. Berger, C.; Song, Z. M.; Li, T. B.; Li, X. B.; Ogbazghi, A. Y.; Feng, R.; Dai, Z. T.; Marchenkov, A. N.; Conrad, E. H.; First, P. N.; de Heer, W. A., Ultrathin epitaxial graphite: 2D electron gas properties and a route toward graphene-based nanoelectronics. J. Phys. Chem. B 2004, 108, 19912-19916.
15.Li, X. S.; Cai, W. W.; An, J. H.; Kim, S.; Nah, J.; Yang, D. X.; Piner, R.; Velamakanni, A.; Jung, I.; Tutuc, E.; Banerjee, S. K.; Colombo, L.; Ruoff, R. S., Large-Area Synthesis of High-Quality and Uniform Graphene Films on Copper Foils. Science 2009, 324, 1312-1314.
16. Kim, K.; Choi, J. Y.; Kim, T.; Cho, S. H.; Chung, H. J., A role for graphene in silicon-based semiconductor devices. Nature 2011, 479, 338-344.
17. Bae, S.; Kim, H.; Lee, Y.; Xu, X. F.; Park, J. S.; Zheng, Y.; Balakrishnan, J.; Lei, T.; Kim, H. R.; Song, Y. I.; Kim, Y. J.; Kim, K. S.; Ozyilmaz, B.; Ahn, J. H.; Hong, B. H.; Iijima, S., Roll-to-roll production of 30-inch graphene films for transparent electrodes. Nat. Nanotechnol. 2010, 5, 574-578.
18. Son, M.; Ham, M.-H., Low-temperature synthesis of graphene by chemical vapor deposition and its applications. FlatChem 2017, 5, 40-49.
19. Bai, J.; Zhong, X.; Jiang, S.; Huang, Y.; Duan, X., Graphene nanomesh.Nat. Nanotechnol. 2010, 5, 190.
20. Sinitskii, A.; Tour, J. M., Patterning Graphene through the Self-Assembled Templates: Toward Periodic Two-Dimensional Graphene Nanostructures with Semiconductor Properties. J. Am. Chem. Soc. 2010, 132, 14730-14732.
21. Venkatesan, B. M.; Bashir, R., Nanopore sensors for nucleic acid analysis.Nat. Nanotechnol. 2011, 6, 615-624.
22. Garaj, S.; Hubbard, W.; Reina, A.; Kong, J.; Branton, D.; Golovchenko, J. A., Graphene as a subnanometre trans-electrode membrane. Nature 2010, 467, 190-193.
23. Sint, K.; Wang, B.; Kral, P., Selective Ion Passage through Functionalized Graphene Nanopores. J. Am. Chem. Soc. 2008, 130, 16448-16449.
24. Rollings, R. C.; Kuan, A. T.; Golovchenko, J. A., Ion selectivity of graphene nanopores. Nat. Commun. 2016, 7, 11408.
25. Jiang, D.-E.; Cooper, V. R.; Dai, S., Porous Graphene as the Ultimate Membrane for Gas Separation. Nano Lett. 2009, 9, 4019-4024.
26. Koenig, S. P.; Wang, L.; Pellegrino, J.; Bunch, J. S., Selective molecular sieving through porous graphene. Nat. Nanotechnol. 2012, 7, 728-732.
27.Cohen-Tanugi, D.; Grossman, J. C., Water Desalination across Nanoporous Graphene. Nano Lett. 2012, 12, 3602-3608.
28. Surwade, S. P.; Smirnov, S. N.; Vlassiouk, I. V.; Unocic, R. R.; Veith, G. M.; Dai, S.; Mahurin, S. M., Water desalination using nanoporous single-layer graphene. Nat. Nanotechnol. 2015, 10, 459-464.
29. Wei, D.; Liu, Y.; Wang, Y.; Zhang, H.; Huang, L.; Yu, G., Synthesis of N-Doped Graphene by Chemical Vapor Deposition and Its Electrical Properties. Nano Lett. 2009, 9, 1752-1758.
30. Wang, Y.; Shao, Y.; Matson, D. W.; Li, J.; Lin, Y., Nitrogen-Doped Graphene and Its Application in Electrochemical Biosensing. ACS Nano 2010, 4, 1790-1798.
31. Shao, Y.; Zhang, S.; Engelhard, M. H.; Li, G.; Shao, G.; Wang, Y.; Liu, J.; Aksay, I. A.; Lin, Y., Nitrogen-doped graphene and its electrochemical applications. J. Mater. Chem. 2010, 20, 7491.
32. Sheng, Z.-H.; Zheng, X.-Q.; Xu, J.-Y.; Bao, W.-J.; Wang, F.-B.; Xia, X.-H., Electrochemical sensor based on nitrogen doped graphene: Simultaneous determination of ascorbic acid, dopamine and uric acid. Biosensors and Bioelectronics 2012, 34, 125-131.
33. Xu, H.; Ma, L.; Jin, Z., Nitrogen-doped graphene: Synthesis, characterizations and energy applications. Journal of Energy Chemistry 2018, 27, 146-160.
34. Wang, H. B.; Maiyalagan, T.; Wang, X., Review on Recent Progress in Nitrogen-Doped Graphene: Synthesis, Characterization, and Its Potential Applications. ACS Catal. 2012, 2, 781-794.
35. Kim, H.; Lee, K.; Woo, S. I.; Jung, Y., On the mechanism of enhanced oxygen reduction reaction in nitrogen-doped graphene nanoribbons. Phys. Chem. Chem. Phys. 2011, 13, 17505-17510.
36. Yoon, D.; Son, Y.-W.; Cheong, H., Negative Thermal Expansion Coefficient of Graphene Measured by Raman Spectroscopy. Nano Lett. 2011, 11, 3227-3231.
37.Deng, S.; Berry, V., Wrinkled, rippled and crumpled graphene: an overview of formation mechanism, electronic properties, and applications. Materials Today 2016, 19, 197-212.
38. Ferrari, A. C.; Meyer, J. C.; Scardaci, V.; Casiraghi, C.; Lazzeri, M.; Mauri, F.; Piscanec, S.; Jiang, D.; Novoselov, K. S.; Roth, S.; Geim, A. K., Raman spectrum of graphene and graphene layers. Phys. Rev. Lett. 2006, 97, 187401.
39. Ferrari, A. C.; Basko, D. M., Raman spectroscopy as a versatile tool for studying the properties of graphene. Nat. Nanotechnol. 2013, 8, 235-246.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the disclosed subject matter (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or example language (e.g., “such as”) provided herein, is intended merely to better illuminate the disclosed subject matter and does not pose a limitation on the scope of the invention unless otherwise claimed. No language in the specification should be construed as indicating any non-claimed element as essential to the practice of the invention.

Certain embodiments are described herein. Variations of those embodiments may become apparent to those of ordinary skill in the art upon reading the foregoing description. The inventors expect skilled artisans to employ such variations as appropriate, and the inventors intend for the embodiments to be practiced otherwise than as specifically described herein. Accordingly, this disclosure includes all modifications and equivalents of the subject matter recited in the claims appended hereto as permitted by applicable law. Moreover, any combination of the above-described elements in all possible variations thereof is encompassed by the disclosure unless otherwise indicated herein or otherwise clearly contradicted by context.

1. A method of forming a graphene layer, comprising:
forming a polymer layer on a catalytic substrate by chemical vapor deposition of a graphene precursor on the catalytic substrate; and
raising a temperature of the polymer layer to at least about 160° C. to induce cyclodehydrogenation of the polymer layer to form a graphene layer on the catalytic substrate.

2. The method according to claim 1, wherein the graphene precursor comprises a polycyclic compound.

3. A method of forming a graphene layer, comprising:
providing a catalytic substrate;
depositing a graphene precursor on the catalytic substrate by chemical vapor deposition of the graphene precursor to form a polymer layer on the catalytic substrate; and
raising a temperature of the polymer layer to at least about 160° C. to induce cyclodehydrogenation of the graphene precursor to form a graphene layer on the catalytic substrate.

4. The method according to claim 3, wherein the graphene precursor comprises a polycyclic compound.

5. The method according to claim 3, wherein the graphene precursor comprises a halogenated polycyclic aromatic compound.

6. The method of claim 3, wherein the graphene precursor comprises 3′,6′-dihalo-1,1′:2′,″-terphenyl (C₁₈H₁₂X₂), wherein Xis selected from Cl, Br, I or a combination thereof.

7. The method of claim 3, wherein the graphene precursor comprises 6,11-dihalo-1,2,3,4-tetraphenyltriphenylene (C₄₂H₂₆X₂), wherein X is selected from Cl, Br, I or a combination thereof.

8. The method of claim 3, wherein the graphene precursor comprises 2,3-di([1,1′-biphenyl]-4-yl)-6,11-dihalo-1,4-diphenyltriphenylene (C₅₄H₃₄X₂), wherein X is selected from Cl, Br, I or a combination thereof.

9. The method of claim 3, wherein the graphene precursor comprises 2-([1,1′:2′,1″-terphenyl]-3′-yl)-6,11-dihalo-1,4-diphenyltriphenylene (C₄₈H₃₀X₂), wherein X is selected from Cl, Br, I or a combination thereof.

10. The method according to claim 3, wherein the catalytic substrate comprises a metal substrate.

11. The method according to claim 10, wherein the metal substrate comprises one of Ni, Cu, Ag, Au, Al, Pd, Rh, Ir or Pt.

12. The method according to claim 3, wherein the catalytic substrate comprises polycrystalline Cu.

13. The method according to claim 3, wherein the raising the temperature induces planarization of the graphene layer.

14. The method according to claim 3, wherein the catalytic substrate is provided in a vacuum chamber.

15. The method of claim 3, wherein the catalytic substrate includes a catalytic material on a flexible, plastic substrate.

16. The method of claim 3, wherein the graphene layer is a graphene monolayer.

17. The method of claim 3, wherein the graphene precursor has carbon (C) atoms specifically substituted with group 13 elements, such as boron (B) atoms, and wherein the graphene layer comprises group-13-element-doped graphene such as B-doped graphene.

18. The method of claim 3, wherein the graphene precursor has carbon (C) atoms specifically substituted with nitrogen (N) atoms and wherein the graphene layer comprises N-doped graphene.

19. The method of claim 3, wherein the graphene precursor has carbon (C) atoms specifically substituted with sulfur (S) atoms and wherein the graphene layer comprises S-doped graphene.

20. The method of claim 3, wherein the graphene precursor contains N and S atoms and wherein the graphene layer comprises N,S-doped graphene, or wherein the graphene precursor contains B and N atoms and wherein the graphene layer comprises B,N-doped graphene.
